(19) United States
(12) Patent Application Publication
(10) Pub. No.: US 2011/0134610 A1
(43) Pub. Date: Jun. 9, 2011

(54) ELECTRONIC MODULE

(75) Inventors: FRANK BAUR, Nurnberg (DE); ROLAND BREY, Eschlkam (DE)

(73) Assignee: CONTINENTAL AUTOMOTIVE GMBH, MUNICH (DE)

(21) Appl. No.: 12/959,615

(22) Filed: Dec. 3, 2010

(30) Foreign Application Priority Data
Dec. 3, 2009 (DE) 10 2009 056 782.8

(51) Int. Cl. H05K 7/20

(52) U.S. Cl. 361/720

(57) ABSTRACT

An electronic module contains a printed circuit board having a conductor track structure and at least one receiving surface. The electronic module further contains at least one electronic component which is disposed on the at least one receiving surface and electrically connected to the conductor track structure. A coolant conducting structure is embodied in the printed circuit board and in which a cooling medium circulates during the operation of the electronic module. A section of the coolant conducting structure in the region of the at least one receiving surface being formed by a wall of the printed circuit board and a surface of the electronic component.

### CROSS-REFERENCE TO RELATED APPLICATION

This application claims the priority, under 35 U.S.C. §119, of German application DE 10 2009 056 782.8, filed Dec. 3, 2009; the prior application is herewith incorporated by reference in its entirety.

### BACKGROUND OF THE INVENTION

### Field of the Invention

The invention relates to an electronic module which is formed with a printed circuit board having a conductor track structure and having at least one electronic component which is disposed on a receiving surface of the printed circuit board and electrically connected to the conductor track structure. Embodied in the printed circuit board is a coolant conducting structure which is connected to a heat sink and in which a cooling medium circulates during the operation of the electronic module, a section of the coolant conducting structure in the region of the at least one receiving surface being formed by a wall of the printed circuit board and a surface of the electronic component.

An electronic module of this kind is known from European patent application EP 1 628 515 A1, corresponding to U.S. Pat. No. 7,215,547. The module is formed with a base on the surface of which a coolant pump is disposed directly.

Electronic components such as e.g. semiconductor switching elements, integrated circuits and the like are subject to a high dissipation loss during operation, with the result that they heat up considerably in some cases. Such high temperatures can occur locally in these circumstances that the electronic component itself or the electrical connection of the electronic component to the printed circuit board is damaged. Points having local temperature peaks are referred to as “hotspots”. The heat generated in particular at the hotspots must be conducted away from the electronic components in order to be able to ensure their reliability and service life over a required period of time.

Typically, in order to prevent self-heating beyond a critical temperature value during the operation of the electronic module, heat-conducting materials are employed for the purpose of directing the heat away from the point of origin. In the region of the electronic component the printed circuit board has for this purpose either a so-called copper inlay or a number of metal-filled microvias which conduct the heat away from the electronic component. The printed circuit board is furthermore connected via a heat-conducting material, such as e.g. thermally conductive paste, to a package component which is in thermal connection with the environment acting as a heat sink to which the heat is dissipated.

However, these measures are not adequate for efficiently conducting away the heat being generated locally in an electronic component and consequently for meeting the requirements with regard to the reliability and service life of the electronic module.

### SUMMARY OF THE INVENTION

It is accordingly an object of the invention to provide an electronic module which overcomes the above-mentioned disadvantages of the prior art devices of this general type, which has improved reliability and an extended service life.

With the foregoing and other objects in view there is provided, in accordance with the invention an electronic module. The electronic module contains a printed circuit board having a conductor track structure and a receiving surface, at least one electronic component disposed on the receiving surface of the printed circuit board and electrically connected to the conductor track structure, a heat sink, and a coolant conducting structure embodied in the printed circuit board and connected to the heat sink. In the coolant conducting structure, a cooling medium circulates during operation of the electronic module. The coolant conducting structure has a section in a region of the receiving surface being formed by a wall of the printed circuit board and a surface of the electronic component. A package component is provided. The printed circuit board is connected in a heat-conducting manner to the package component. The coolant conducting structure is routed through the package component and is connected to the heat said sink outside of the package component.

The invention provides an electronic module which contains a printed circuit board having a conductor track structure and at least one receiving surface. At least one electronic component is disposed on the at least one receiving surface and is electrically connected to the conductor track structure. The electronic module further contains a coolant conducting structure which is embodied in the printed circuit board and in which a cooling medium circulates during the operation of the electronic module. A section of the coolant conducting structure in the region of the at least one receiving surface is formed by a wall of the printed circuit board and a surface of the electronic component. It is furthermore provided that the coolant conducting structure is connected to a heat sink. The heat sink can be, for example, a heat-conducting material which is connected to the environment. In addition the printed circuit board is connected in a heat-conducting manner, optionally by way of a thermally conductive material, to a package component. The package component can be a constituent part of a package of the module which mechanically protects the printed circuit board and the electronic components disposed thereon. A thermally conductive paste, for example, is suitable as a heat-conducting material. The coolant conducting structure is routed through the package component and connected to the heat sink outside of the package.

By use of the electronic module according to the invention the heat can be transported away directly from the point of origin of the electronic component or components by the cooling medium. As a result the absolute temperature in the electronic component or components is lowered, thereby increasing its reliability. The coolant conducting structure according to the invention, which is embodied in part also by a respective electronic component requiring to be cooled, can be integrated in the printed circuit board in a space-saving manner. Moreover, compared to conventional solutions there is no longer any need for additional materials or devices for carrying away the heat being generated in the electronic component(s).

The at least one electronic component is beneficially connected in a fluid-tight manner to the printed circuit board in order to form the section of the coolant conducting structure. By this measure it is ensured that the cooling medium circulating in the coolant conducting structure cannot escape from the latter and inadvertently cause short-circuits.

For cooling purposes the cooling medium flows in particular directly past the at least one component. Therefore the cooling medium impinges on the electronic component requiring to be cooled without a heat conductor being inserted as intermediary and transports the heat being generated in the component away. This guarantees a maximum of cooling efficiency, since no other materials are provided between the cooling medium and the electronic component.

According to a further embodiment the surface of the electronic component forming a section of the coolant conducting structure is at least a part of a main side of the electronic component. Beneficially, the electronic component is electrically contacted on the main side impinged upon by the cooling medium. The main side, which is also referred to as the contact side, can be electrically connected to the printed circuit board by way of a ball grid array or by way of bonding wires, for example. In the case of an electrical connection by a ball grid array (BGA) the cooling medium flows through between the balls between the wall of the printed circuit board and the contact side of the electronic component. If the electronic component is connected by its back side to the printed circuit board and electrically contacted by way of bonding wires, the cooling medium will flow around the front side of the electronic component.

In one embodiment the coolant conducting structure contains plated through holes (or “vias”) embodied as channels which extend at least in sections through the printed circuit board vertically with respect to a respective receiving surface and embody an inflow and outflow for the cooling medium. In this case the diameter of the plated through holes is preferably selected such that the cooling medium can flow through the plated through holes without significant flow resistance. An arbitrary number of coolant conducting sections formed between a wall of the printed circuit board and a surface of the electronic component can be connected between inflow and outflow. Accordingly, the coolant conducting structure either has an inflow and outflow for each electronic component or, alternatively, a plurality of electronic components requiring to be cooled can be connected to one inflow and outflow.

The walls of the plated through holes are beneficially lined with a sealing layer. The layer can consist, for example, of copper which can be produced together with the plated through holes (vias) for electrical conducting purposes.

In order to avoid the electronic component or components requiring to be cooled being damaged as a result of a short-circuit induced by the cooling medium it is further provided that the cooling medium be electrically insulating. Glycol, for example, can be chosen as the cooling medium.

The circulation of the cooling medium can be optionally effected either by natural convection or by a pump. For example, a pump of can be connected to the coolant conducting structure on the printed circuit board or outside of the package, e.g. in close physical proximity to the heat sink.

Other features which are considered as characteristic for the invention are set forth in the appended claims.

Although the invention is illustrated and described herein as embodied in an electronic module, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, cross-sectional view of a first exemplary embodiment of an electronic module according to the invention; and

FIG. 2 is a diagrammatic, cross-sectional view of a second exemplary embodiment of the electronic module according to the invention.

### DETAILED DESCRIPTION OF THE INVENTION

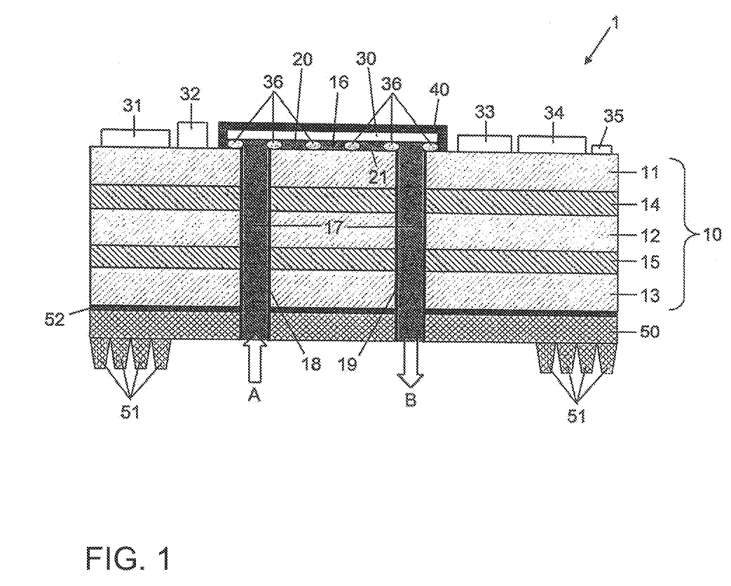

Referring now to the figures of the drawing in detail and first, particularly, to FIG. 1 thereof, there is shown a schematic cross-sectional view of an electronic module 1 according to the invention. The module 1 contains a printed circuit board 10 consisting of, by way of example, three printed circuit board layers 11, 12, 13, which are in each case connected to one another by way of conducting layers 14, 15. The printed circuit board 10 shown in the exemplary embodiment therefore constitutes a multi-layer printed circuit board. The electronic module 1 according to the invention could, of course, also simply contain a single printed circuit board layer. Equally, a different number of printed circuit board layers—with or without intermediate conducting layers—could be provided.

Likewise merely by way of example, an electronic component 30 requiring to be cooled is disposed on a receiving surface 16 on a main side of the printed circuit board 10. Also provided on the same main side of the printed circuit board 10 are further electronic components 31, 32, 33, 34, 35 which because of their configuration and/or mode of operation require no cooling according to the invention. Although it cannot be seen in the cross-sectional view of FIG. 1, the electronic components 30, 31, 32, 33, 34, 35 are electrically connected to one another by way of a non-illustrated conductor track structure on and/or in the printed circuit board 10.

A coolant conducting structure 17 is embodied in the printed circuit board 10 below the receiving surface 16. In the exemplary embodiment the coolant conducting structure 17 contains a channel 18 and a channel 19, each of which extends essentially vertically through the printed circuit board 10. Contrary to the graphical representation of FIG. 1, the channels 18, 19 do not need to extend along a single axis through the printed circuit board 10. Rather, the channels 18, 19 can basically be routed through the printed circuit board 10 in any desired manner. Only in the printed circuit board layer 11 on which the electronic component 30 requiring to be cooled is disposed is it necessary for the channel sections of the channels 18, 19 to be disposed in the region of the receiving surface 16 of the component 30. In other words, the channel sections must be provided within a contour of the component 30 so that they can be sealed off from the environment.

The channels 18, 19 are embodied as what are termed plated through holes (vias), the walls of which are lined with a sealing layer made of copper. The sealing layer can be produced together with vias that are possibly provided in addition for electrical conducting purposes. The channel 18 serves as an inflow (arrow A) for a cooling medium circulating in the coolant conducting structure. The channel 19 serves as an outflow (arrow B) for the cooling medium. In the region of the receiving surface 16 a section of the coolant conducting structure 17 is formed by a wall 20 of the printed circuit board 10 and a surface 21 of the electronic component 30.

Because of the manner in which the component 30 chosen in the exemplary embodiment is electrically contacted, namely by way of a ball grid array (BGA), the cooling medium flows into the channel 18, between the “balls” 36, and away through the channel 19. By this measure the heat being generated in the electronic component 30 can be conducted away directly by way of the cooling medium. In this arrangement the cooling medium flows directly past the component 30 in order to cool it, i.e. without a further heat-dissipating element being inserted as an intermediary. Since there exists the risk of short-circuits between respective “balls” due to the type of electrical contacting chosen in the exemplary embodiment, an electrically insulating cooling fluid composed of glycol is used.

As an additional safeguard to ensure that the cooling medium circulating in the coolant conducting structure 17 in the region of the receiving surface 16 cannot escape from the channel system, the electronic component 30 is provided with an encapsulation 40 which seals off the coolant conducting structure from the environment in a fluid-tight manner.

The printed circuit board 10 is arranged on a package component 50 by way of a heat-conducting material 52, e.g. a thermally conductive paste. Cooling fins 51 facing away from the printed circuit board 10 are provided on the package component 50. Preferably provided on the same side of the package component 50 is a heat sink to which the coolant conducting structure 17 is connected. In order to be able to assure the circulation of the cooling medium in the coolant conducting structure, a pump can be provided which, for example, is likewise provided on the side of the electronic module 1 facing away from the printed circuit board 10. In certain situations it may be sufficient to ensure the circulation of the cooling medium through natural convection.

In an embodiment not shown in the FIG. 1, the components 31, 32, 33, 34, 35 arranged adjacent to the electronic component 30 on the printed circuit board 10 can also be connected in a thermally conductive manner to the coolant conducting structure 17. For example, a copper inlay or a number of microvias which conduct the heat to the conducting layer 14 can be provided for this purpose in the printed circuit board layer 11. The conducting layer 14 is in turn connected to the coolant conducting structure 17 in a heat-conducting manner (by virtue of its high proportion of metal).

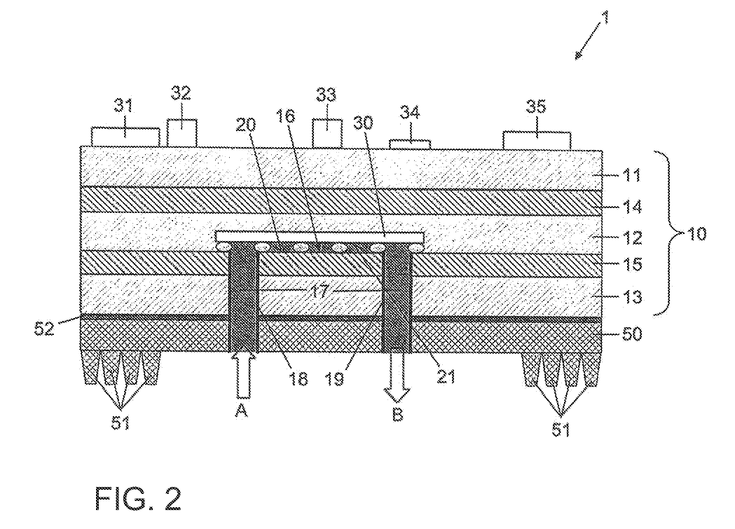

FIG. 2 shows a further exemplary embodiment which differs from the exemplary embodiment shown in FIG. 1 in that the electronic component 30 requiring to be cooled is disposed in the interior of the printed circuit board 10. More precisely, the component 30 is arranged in the region of the printed circuit board layer 12. The component 30 is in turn connected to a conductor track structure of the conducting layer 15 by way of a ball grid array. The advantage of this embodiment variant consists in the fact that a greater number of further components can be arranged on the outside of the printed circuit board 10. Furthermore it is not necessary to seal off the section of the coolant conducting structure that is formed by the wall 20 of the printed circuit board and the surface 21 of the electronic component 30 from the environment. The encapsulation of the electronic component 30 requiring to be cooled can therefore be dispensed with.

In the exemplary embodiments shown in FIGS. 1 and 2, the electronic component 30 requiring to be cooled is contacted by way of a ball grid array. Electrical contacting of the component requiring to be cooled can, of course, also be effected by way of bonding wires, which in that case should then be encapsulated in a fluid-tight manner against their surroundings.

The advantage of the electronic module according to the invention consists in the fact that heat can be transported away directly from the point of origin. The absolute temperature in the components requiring to be cooled can be lowered as a result, thereby increasing their reliability. Using vias and components as cooling channel sections enables the coolant conducting structure to be integrated into the printed circuit board in a space-saving manner. Furthermore, no additional materials or components are required.

1. An electronic module, comprising:
a printed circuit board having a conductor track structure and a receiving surface;
at least one electronic component disposed on said receiving surface of said printed circuit board and electrically connected to said conductor track structure;
a heat sink;
a coolant conducting structure embodied in said printed circuit board and connected to said heat sink and in said coolant conducting structure a cooling medium circulates during operation of said electronic module, said coolant conducting structure having a section in a region of said receiving surface being formed by a wall of said printed circuit board and a surface of said electronic component;
a package component, said printed circuit board connected in a heat-conducting manner to said package component; and
said coolant conducting structure is routed through said package component and connected to said heat said sink outside of said package component.

2. The module according to claim 1, wherein said at least one electronic component is connected to said printed circuit board in a fluid-tight manner for forming said section of said coolant conducting structure.

3. The module according to claim 1, wherein for cooling purposes the cooling medium flows directly past said at least one electronic component.

4. The module according to claim 1, wherein said surface of said electronic component forming a section of said coolant conducting structure is at least a part of a main side of said electronic component.

5. The module according to claim 4, wherein said electronic component is electrically contacted on said main side impinged upon by the cooling medium.

6. The module according to claim 1, wherein said coolant conducting structure has plated through holes embodied as channels which extend at least in sections through said printed circuit board vertically with respect to said receiving surface and embody an inflow and outflow for the cooling medium.

7. The module according to claim 6, wherein said plated through holes have walls lined with a sealing layer.

8. The module according to claim 1, further comprising a thermally conductive material connecting said printed circuit board to said package component in a heat-conducting manner.
